(19) United States
(12) Patent Application Publication
(10) Pub. No.: US 2026/0206238 A1
(43) Pub. Date: Jul. 16, 2026

(54) MEMORY DEVICE AND MANUFACTURING METHOD THEREOF

(71) Applicant: NANYA TECHNOLOGY CORPORATION, New Taipei City (TW)

(72) Inventor: Hsu Chiang, New Taipei City (TW)

(73) Assignee: NANYA TECHNOLOGY CORPORATION, New Taipei City (TW)

(21) Appl. No.: 19/017,764

(22) Filed: Jan. 12, 2025

(51) Int. Cl. H10B 80/00; H01L 23/00; H01L 25/00; H01L 25/065; H01L 25/18

(52) U.S. Cl. CPC H10B 80/00; H10W 90/00; H10W 80/011; H10W 80/312; H10W 80/327; H10W 90/297; H10W 90/792

(57) ABSTRACT

The disclosure provides a manufacturing method of a memory device including providing a first chip, wherein the first chip comprises a first semiconductor layer, a first memory cell disposed on the first semiconductor layer, and a first circuit layer disposed on the first memory cell; providing a second chip, wherein the second chip comprises a second semiconductor layer, a second memory cell disposed on the second semiconductor layer, and a second circuit layer disposed on the second memory cell; and bonding the first chip and the second chip by a hybrid bonding process to form a bonding interface comprising a dielectric-to-dielectric bonding interface and a metal-to-metal bonding interface. A memory device is also provided.

### BACKGROUND

### Technical Field

The present disclosure relates to a memory device and manufacturing method thereof.

### Description of Related Art

Three-dimensional stacking technology has been widely adopted to produce compact high-capacity memory packages. Three-dimensional stacked memory packages usually use micro bumps (such as solder balls) and an underfill for connection and protection. However, the micro bumps and the underfill may derive many problems.

### SUMMARY

The disclosure provides a manufacturing method of a memory device including providing a first chip, wherein the first chip comprises a first semiconductor layer, a first memory cell disposed on the first semiconductor layer, and a first circuit layer disposed on the first memory cell; providing a second chip, wherein the second chip comprises a second semiconductor layer, a second memory cell disposed on the second semiconductor layer, and a second circuit layer disposed on the second memory cell; and bonding the first chip and the second chip by a hybrid bonding process to form a bonding interface comprising a dielectric-to-dielectric bonding interface and a metal-to-metal bonding interface.

The disclosure provides a memory device including a first chip and a second chip. The first chip includes a first semiconductor layer, a first memory cell disposed on the first semiconductor layer, and a first circuit layer disposed on the first memory cell. An end of the first circuit layer comprises a first dielectric portion and a first metal portion. The second chip includes a second semiconductor layer, a second memory cell disposed on the second semiconductor layer, and a second circuit layer disposed on the second memory cell. An end of the second circuit layer includes a second dielectric portion and a second metal portion. The second dielectric portion is directly connecting the first dielectric portion, and the second metal portion is directly connecting the first metal portion.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 to FIG. 4 are cross-sectional views illustrating a manufacturing method of a memory device according to an embodiment of the disclosure.

FIG. 5 is a flow diagram of some embodiments of a manufacturing method of a memory device.

### DESCRIPTION OF THE EMBODIMENTS

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another element, component, region, layer or section. Thus, a first element, component, region, layer or section discussed below could be termed a second element, component, region, layer or section without departing from the teachings of the present inventive concept.

In the three-dimensional stacked memory device, for increasing capacity, dual chips stacking will be used. For example, the dual chips memory stack may be a 3D-stack dynamic random-access memory (3D DRAM). In particular, the dual chips may be connected by the micro bumps, and the underfill may be used to surround the micro bumps for increasing strength of the memory device. However, high resistance of the micro bumps may derive the speed loss issue for design. On the other hand, voids are easily generated during the formation of the underfill, and voids may increase the probability of the failure of the memory device under stress. Further, the underfill usually formed by materials with worse heat dissipation efficiency, it may decrease the reliability of the memory device. In the present disclosure, the aforementioned issues of the micro bumps and the underfill may be improved by using a hybrid bonding process to omit the micro bumps and the underfill between the two chips.

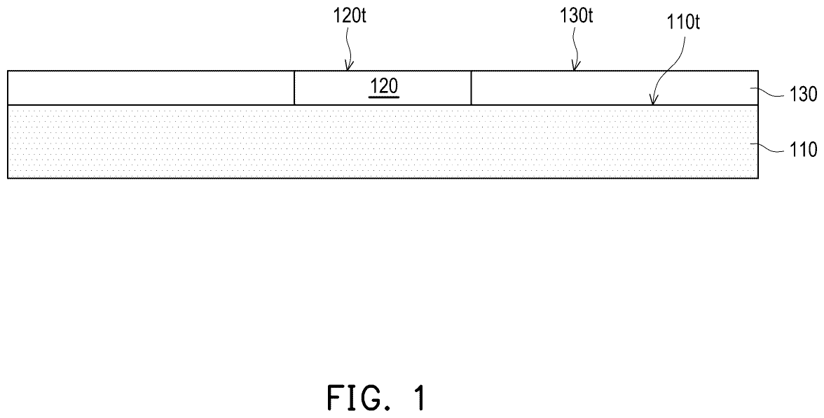

FIG. 1 to FIG. 4 are cross-sectional views illustrating a manufacturing method of a memory device according to an embodiment of the disclosure.

Referring to FIG. 1, a memory cell 120 is formed on a semiconductor layer 110. In unillustrated portion, the semiconductor layer 110 is a silicon layer having at least one suitable doping region, and the memory cell 120 is defined as 1T1C, which refers to a structure including a combination of one transistor and one capacitor. For example, the transistor includes a gate structure, a source region, and a drain region to maintain the operation of the memory cell 120, wherein the gate structure may be formed on the semiconductor layer 110, and the source region/the drain region may be formed in the semiconductor layer 110. Here, the semiconductor layer 110 and the memory cell 120 may be manufactured by suitable general knowledge, the detail is not reiterated here.

And then, an isolation layer 130 may be formed on the semiconductor layer 110 and surrounding the memory cell 120. In some embodiments, the materials of the isolation layer 130 may be formed and covered a surface 110t of the semiconductor layer 110 and a surface 120t of the memory cell 120 (not shown). Next, a planarization process is performed to remove the materials overlying the surface 120t of the memory cell 120, such that the surface 120t of the memory cell 120 and a surface 130t of the isolation layer 130 are substantially coplanar, meanwhile the surface 120t of the memory cell 120 may be exposed. By doing so, flatness for forming subsequent films is increased, and the reliability of the memory device may be improved. Here, the surface 110t of the semiconductor layer 110, the surface 120t of the memory cell 120, and the surface 130t of the isolation layer 130 may be top surfaces in FIG. 1.

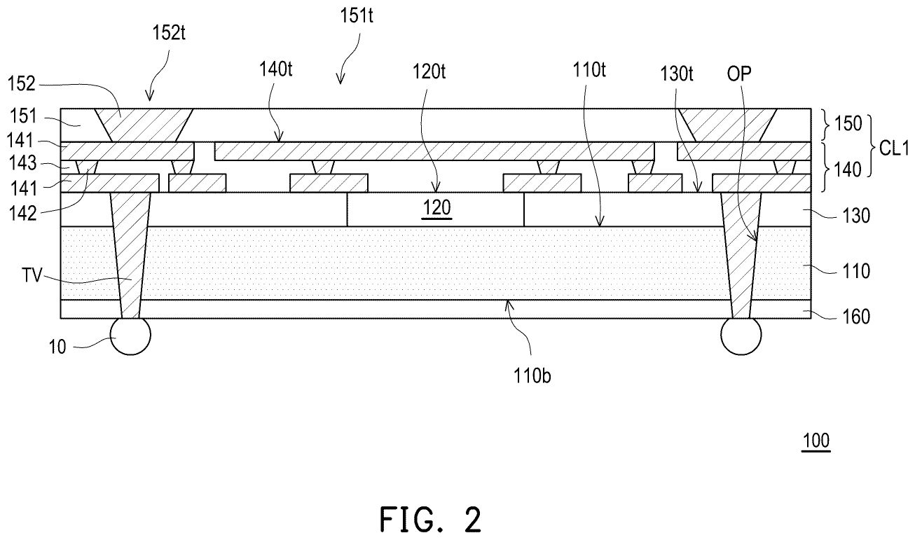

Referring to FIG. 2, a plurality of openings OP may be formed and penetrating through the semiconductor layer 110 and the isolation layer 130. Next, a plurality of through vias TV are formed in the openings OP. In the embodiment, the through vias TV are filled up the openings OP. In some embodiments, the openings OP are formed by photolithography process or the like, and the through vias TV are formed by plating process with the Cu, or the like. In some embodiments, when the semiconductor layer 110 is the silicon layer, an insulating layer may be formed between the through vias TV and the semiconductor layer 110 (not shown), and the through vias TV may be referred as TSVs.

After forming the through vias TV, a circuit layer CL1 is formed on the semiconductor layer 110 and electrically connected to the memory cell 120 and the through vias TV. For example, the circuit layer CL1 includes an interconnect structure 140 and a bonding structure 150, wherein the interconnect structure 140 is directly formed on the surface 120t of the memory cell 120 and the surface 130t of the isolation layer 130, and then the bonding structure 150 is directly formed on a surface 140t of the interconnect structure 140, that is to say, the bonding structure 150 is formed after forming the interconnect structure 140. Here, the surface 140t of the interconnect structure 140 may be a top surface in FIG. 2.

In the embodiment, the interconnect structure 140 includes a plurality of connecting lines 141 and a plurality of connecting vias 142 disposed in a plurality of dielectric layers 143, wherein the connecting lines 141 are electrically connected to the connecting vias 142. In some embodiments, the interconnect structure 140 may use depositing process with conductive materials and dielectric materials, photolithography process, etching process, chemical-mechanical polishing (CMP) process, or other suitable interconnect processes to form. For example, but not limited thereto, the conductive materials may include copper (Cu) or the like, and the dielectric materials include silicon oxide (SiO), phosphosilicate glass (PSG), borophosphosilicate glass (BPSG) or low dielectric constant (k) material, such as fluorosilicate glass (FSG), organosilicate glass (OSG), or a combination thereof.

Further, the bonding structure 150 includes a dielectric portion 151 and a metal portion 152 disposed in the dielectric portion 151, and a bonding surface 151t of the dielectric portion 151 is substantially coplanar with a bonding surface 152t of the metal portion 152. In some embodiments, the bonding structure 150 may use depositing process with conductive materials and dielectric materials, photolithography process, etching process, chemical-mechanical polishing (CMP) process, or other suitable interconnect processes to form. For example, in order to improve the yield of the subsequent bonding process, the dielectric materials of the dielectric portion 151 include silicon oxide (SiO), or silicon carbide nitride (SiCN), and the conductive materials of the metal portion 152 include copper (Cu) or the like. Here, the bonding surface 151t of the dielectric portion 151 and the bonding surface 152t of the metal portion 152 may be top surfaces in FIG. 2.

After forming the circuit layer CL1, portions of the semiconductor layer 110 may be removed, such that portions of the through vias TV are exposed. In some embodiments, an etching process is performed to remove the portions of the semiconductor layer 110. Next, a protection layer 160 is formed on a surface 110b opposite to the surface 110t of the semiconductor layer 110 and surrounding the through vias TV protruded from the semiconductor layer 110. And then, a plurality of external terminals 10 are formed on the through vias TV and electrically connected thereto. In some embodiments, the protection layer 160 is formed by depositing process with oxide, nitride, or the like. In some embodiments, the external terminals 10 may be formed by reflowing process with solder or the like. The manufacturing of a chip 100 is roughly completed via the above steps. It should be noted that the through vias TV also may be formed by other suitable process and may be formed after the bonding process, in this way, the manufacturing complexity of the memory device may be reduced, but the disclosure is not limited to.

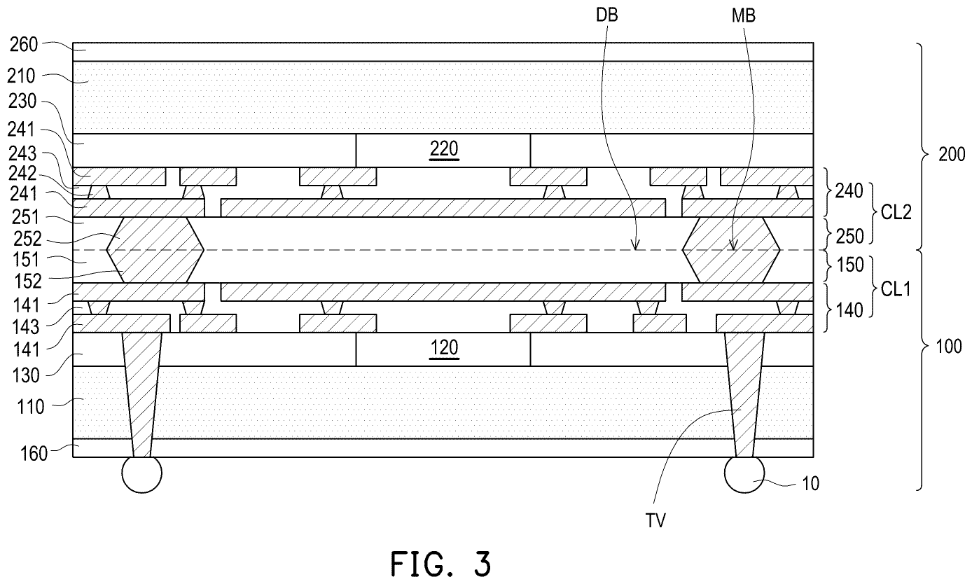

Referring to FIG. 3, a chip 200 may be provided by similar manufacturing method from FIG. 1 to FIG. 2, that is to say, the manufacturing method of a chip 200 is similar to the manufacturing of a chip 100. In particular, a difference between the chip 100 and the chip 200 is that the chip 200 is free from through via penetrating through the semiconductor layer. Here, the structures of the chip 200, such as a semiconductor layer 210, a memory cell 220, an isolation layer 230, a circuit layer CL2 including a interconnect structure 240 (connecting lines 241, connecting vias 242, and dielectric layers 243) and a bonding structure 250 (a dielectric portion 251 and a metal portion 252) and a protection layer 260, are similar to the structures of the chip 100, such as semiconductor layer 110, the memory cell 120, the isolation layer 130, the circuit layer CL1 including the interconnect structure 140 (the connecting lines 141, the connecting vias 142, and the dielectric layers 143) and the bonding structure 150 (the dielectric portion 151 and the metal portion 152), and the protection layer 160 respectively, and are not reiterated here. In the embodiment, the chip 100 may be a master chip and the chip 200 may be a slave chip in functionality.

After the chip 100 and the chip 200 are provided, the chip 100 and the chip 200 may be bonded by a hybrid bonding process to form a bonding interface comprising a dielectric-to-dielectric bonding interface DB and a metal-to-metal bonding interface MB. In the embodiment, the hybrid bonding process may be performed by following steps. First, one plasma process is performed on the dielectric portion 151 of the circuit layer CL1 and another one plasma process is performed on the dielectric portion 251 of the circuit layer CL2 to charge the bonding surfaces of the circuit layer CL1, CL2. Next, the dielectric portion 151 and the dielectric portion 251 are directly contacted (may be by stress) to form a van der Waals bonding, thereby the dielectric-to-dielectric bonding interface DB is formed. When the dielectric portion 151 and the dielectric portion 251 are contacted, the metal portion 152 of the circuit layer CL1 and the metal portion 252 of the circuit layer CL2 may also be directly contacted simultaneously. After forming the dielectric-to-dielectric bonding interface DB, an annealing process is performed on the metal portion 152 and the metal portion 252 to form the metal-to-metal bonding interface MB.

In the embodiment, the aforementioned two plasma processes are performed at room temperature (such as 25° C.), that is to say, the dielectric-to-dielectric bonding interface DB may be formed without heating. In addition, the annealing process is performed at a range between 300° C. and 350° C., but the disclosure is not limited to.

In some embodiments, a width of the metal portion 152 of the circuit layer CL1 of the chip 100 is gradually increased toward the chip 200, and a width of the metal portion 252 of the circuit layer CL2 of the chip 200 is gradually increased toward the chip 100, such that bonding areas between the chip 100 and the chip 200 may be increased, thereby bonding quality may be improved, but the disclosure is not limited to, the metal portion 152 and the metal portion 252 may have other suitable shapes.

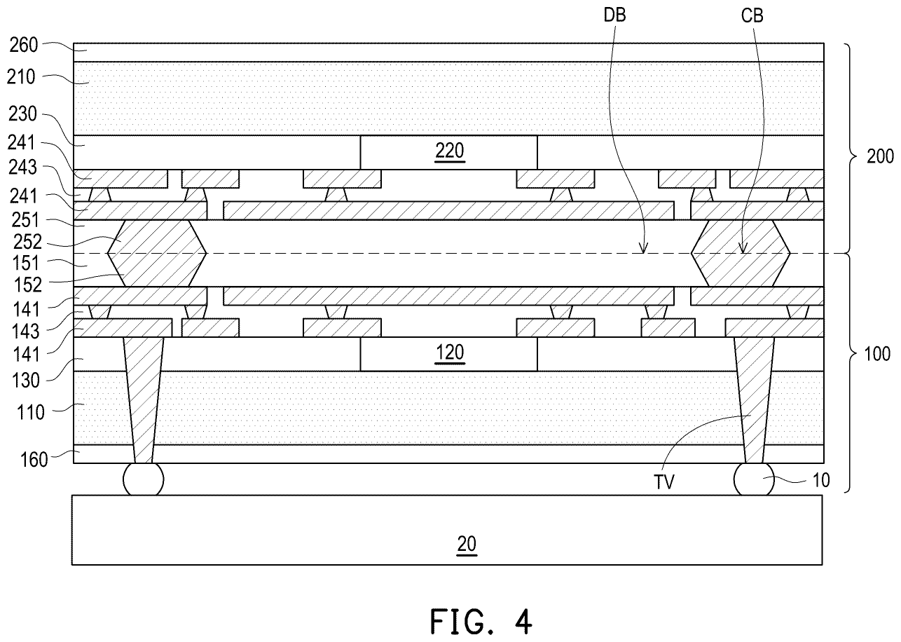

Referring to FIG. 4, a substrate 20 is provided, and the chip 100 and the chip 200 may be bonded on the substrate 20 through the external terminals 10. For example, the external terminals 10, the chip 100, and the chip 200 are stacked on the substrate 20 sequentially. In some embodiments, the substrate 20 may be a printed circuit board (PCB), a semiconductor substrate or other substrates known in the art.

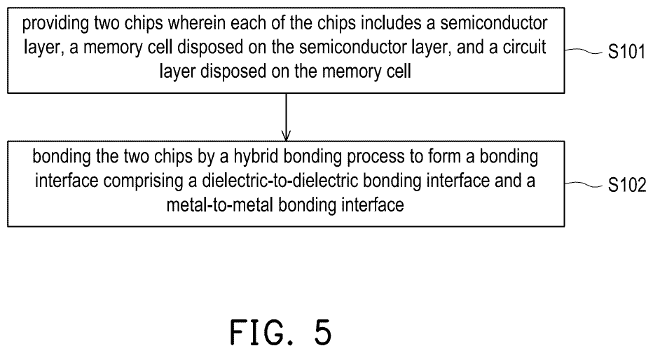

FIG. 5 is a flow diagram of some embodiments of a manufacturing method of a memory device. The method includes a number of operations (blocks S101, S102). The description and illustration are not deemed as a limitation to the sequence of the operations.

At block S101, provide two chips wherein each of the chips includes a semiconductor layer, a memory cell disposed on the semiconductor layer, and a circuit layer disposed on the memory cell. FIG. 1 to FIG. 3 illustrate cross-sectional views of some embodiments corresponding to block 101.

At block S102, bond the two chips by a hybrid bonding process to form a bonding interface comprising a dielectric-to-dielectric bonding interface and a metal-to-metal bonding interface. FIG. 3 illustrate a cross-sectional view of some embodiments corresponding to block 102.

In the disclosure, the manufacturing method of the memory device is introduced the hybrid bonding process to form the physical connection and the electrical connection between two chips, therefore, the micro bumps and the underfill may be omitted. To be specific, the speed loss issue from the micro bumps is avoided, while the voids and the heat dissipation efficiency issues from the underfill are also avoided, thereby performance and reliability of the memory device may be improved.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A manufacturing method of a memory device, comprising:
providing a first chip, wherein the first chip comprises a first semiconductor layer, a first memory cell disposed on the first semiconductor layer, and a first circuit layer disposed on the first memory cell;
providing a second chip, wherein the second chip comprises a second semiconductor layer, a second memory cell disposed on the second semiconductor layer, and a second circuit layer disposed on the second memory cell; and
bonding the first chip and the second chip by a hybrid bonding process to form a bonding interface comprising a dielectric-to-dielectric bonding interface and a metal-to-metal bonding interface.

2. The manufacturing method of a memory device as claimed in claim 1, wherein the hybrid bonding process further comprising:
performing a first plasma process on a first dielectric portion of the first circuit layer;
performing a second plasma process on a second dielectric portion of the second circuit layer; and
contacting the first dielectric portion and the second dielectric portion to form a van der Waals bonding.

3. The manufacturing method of a memory device as claimed in claim 2, wherein the first plasma process and the second plasma process are performed at room temperature.

4. The manufacturing method of a memory device as claimed in claim 1, wherein the hybrid bonding process further comprising:
contacting a first metal portion of the first circuit layer and a second metal portion of the second circuit layer; and
performing an annealing process on the first metal portion and the second metal portion.

5. The manufacturing method of a memory device as claimed in claim 4, wherein the annealing process is performed at a range between 300° C. and 350° C.

6. The manufacturing method of a memory device as claimed in claim 1, further comprising:
forming through vias in the first chip, and the through vias are penetrating through the first semiconductor layer.

7. The manufacturing method of a memory device as claimed in claim 6, further comprising:
forming external terminals on the through vias.

8. The manufacturing method of a memory device as claimed in claim 7, further comprising:
providing a substrate; and
the first chip and the second chip are bonded on the substrate through the external terminals.

9. The manufacturing method of a memory device as claimed in claim 1, wherein the dielectric-to-dielectric bonding interface is formed with silicon oxide or silicon carbide nitride.

10. The manufacturing method of a memory device as claimed in claim 1, wherein metal-to-metal bonding interface is formed with Cu.

11. The manufacturing method of a memory device as claimed in claim 1, wherein:
the first memory cell is formed before forming the first circuit layer; and
the second memory cell is formed before forming the second circuit layer.

12. A memory device, comprising:
a first chip, comprising a first semiconductor layer, a first memory cell disposed on the first semiconductor layer, and a first circuit layer disposed on the first memory cell, wherein an end of the first circuit layer comprises a first dielectric portion and a first metal portion; and
a second chip, comprising a second semiconductor layer, a second memory cell disposed on the second semiconductor layer, and a second circuit layer disposed on the second memory cell, wherein an end of the second circuit layer comprises a second dielectric portion and a second metal portion, the second dielectric portion is directly connecting the first dielectric portion, and the second metal portion is directly connecting the first metal portion.

13. The memory device as claimed in claim 12, wherein the first chip further comprising: through vias penetrating through the first semiconductor layer and connecting to the first circuit layer.

14. The memory device as claimed in claim 13, further comprising: external terminals disposed on the through vias.

15. The memory device as claimed in claim 14, further comprising: a substrate, wherein the external terminals, the first chip, and the second chip are stacked on the substrate sequentially.

16. The memory device as claimed in claim 12, wherein the first dielectric portion and the second dielectric portion comprise silicon oxide or silicon carbide nitride.

17. The memory device as claimed in claim 12, wherein the first metal portion and the second metal portion comprise Cu.

18. The memory device as claimed in claim 12, wherein:
the first chip further comprises a first isolation layer surrounding the first memory cell;
a surface of the first memory cell and a surface of the first isolation layer are coplanar;
the second chip further comprises a second isolation layer surrounding by the second memory cell; and
a surface of the second memory cell and a surface of the second isolation layer are coplanar.

19. The memory device as claimed in claim 12, wherein the second chip is free from through via penetrating through the second semiconductor layer.

20. The memory device as claimed in claim 12, wherein:
a width of the first metal portion is gradually increased toward the second chip; and
a width of the second metal portion is gradually increased toward the first chip.
